(19) United States
(12) Patent Application Publication
(10) Pub. No.: US 2006/0042830 A1
(43) Pub. Date: Mar. 2, 2006

(54) Flexible multi-level cable

(75) Inventors: Mariam N. Maghribi, Livermore, CA (US); Peter A. Krulevitch, Pleasanton, CA (US); James Courtney Davidson, Livermore, CA (US); Julie K. Hamilton, Tracy, CA (US)

Correspondence Address: Eddie E. Scott;Assistant Laboratory Counsel, Lawrence Livermore National Laboratory, P.O. Box 808, L-703, Livermore, CA, 94551, US

(73) Assignee: The Regents of the University of California

(21) Appl. No.: 10/926,882

(22) Filed: Aug. 25, 2004

(51) Int. Cl. H05K 1/03

(52) U.S. Cl. 174/256; 174/258

(57) ABSTRACT

A flexible cable comprises a cable body of a silicone material and circuits in the flexible cable body. In one embodiment the flexible cable body comprises a multiple number of individual layers of poly(dimethylsiloxane). In one embodiment silicone material encapsulates the individual layers. The flexible cable is made by providing a multiplicity of substrates of a flexible silicone material, producing circuits in the substrates, and stacking the multiplicity of substrates to produce the high density flexible cable.

The United States Government has rights in this invention pursuant to Contract No. W-7405-ENG-48 between the United States Department of Energy and the University of California for the operation of Lawrence Livermore National Laboratory.

### BACKGROUND

1. Field of Endeavor

The present invention relates to cables and more particularly to a multi-level cable.

2. State of Technology

U.S. Pat. No. 4,573,481 for an implantable electrode array by Leo A. Bullara, patented Mar. 4, 1986 provides the following background information, “It has been known for almost 200 years that muscle contraction can be controlled by applying an electrical stimulus to the associated nerves. Practical long-term application of this knowledge, however, was not possible until the relatively recent development of totally implantable miniature electronic circuits which avoid the risk of infection at the sites of percutaneous connecting wires. A well-known example of this modern technology is the artificial cardiac pacemaker which has been successfully implanted in many patients. Modern circuitry enables wireless control of implanted devices by wireless telemetry communication between external and internal circuits. That is, external controls can be used to command implanted nerve stimulators to regain muscle control in injured limbs, to control bladder and sphincter function, to alleviate pain and hypertension, and to restore proper function to many other portions of an impaired or injured nerve-muscle system. To provide an electrical connection to the peripheral nerve which controls the muscles of interest, an electrode (and sometimes an array of multiple electrodes) is secured to and around the nerve bundle. A wire or cable from the electrode is in turn connected to the implanted package of circuitry.”

U.S. Pat. No. 6,052,624 for a directional programming for implantable electrode arrays by Carla M. Mann, patented Apr. 18, 2000 provides the following background information, “Within the past several years, rapid advances have been made in medical devices and apparatus for controlling chronic intractable pain. One such apparatus involves the implantation of an electrode array within the body to electrically stimulate the area of the spinal cord that conducts electrochemical signals to and from the pain site. The stimulation creates the sensation known as paresthesia, which can be characterized as an alternative sensation that replaces the pain signals sensed by the patient. One theory of the mechanism of action of electrical stimulation of the spinal cord for pain relief is the “gate control theory.” This theory suggests that by simulating cells wherein the cell activity counters the conduction of the pain signal along the path to the brain, the pain signal can be blocked from passage. Spinal cord stimulator and other implantable tissue stimulator systems come in two general types: “RF” controlled and fully implanted. The type commonly referred to as an “RF” system includes an external transmitter inductively coupled via an electromagnetic link to an implanted receiver that is connected to a lead with one or more electrodes for stimulating the tissue. The power source, e.g., a battery, for powering the implanted receiver-stimulator as well as the control circuitry to command the implant is maintained in the external unit, a hand-held sized device that is typically worn on the patient's belt or carried in a pocket. The data/power signals are transcutaneously coupled from a cable-connected transmission coil placed over the implanted receiver-stimulator device. The implanted receiver-stimulator device receives the signal and generates the stimulation. The external device usually has some patient control over selected stimulating parameters, and can be programmed from a physician programming system.”

U.S. Pat. No. 6,230,057 for a multi-phasic microphotodiode retinal implant and adaptive imaging retinal stimulation system by Vincent Chow and Alan Chow, patented May 8, 2001 and assigned to Optobionics Corporation provides the following background information, “A variety of retinal diseases cause vision loss or blindness by destruction of the vascular layers of the eye including the choroid, choriocapillaris, and the outer retinal layers including Bruch's membrane and retinal pigment epithelium. Loss of these layers is followed by degeneration of the outer portion of the inner retina beginning with the photoreceptor layer. Variable sparing of the remaining inner retina composed of the outer nuclear, outer plexiform, inner nuclear, inner plexiform, ganglion cell and nerve -fiber layers, may occur. The sparing of the inner retina allows electrical stimulation of this structure to produce sensations of light. Prior efforts to produce vision by electrically stimulating various portions of the retina have been reported. One such attempt involved an externally powered photosensitive device with its photoactive surface and electrode surfaces on opposite sides. The device theoretically would stimulate the nerve fiber layer via direct placement upon this layer from the vitreous body side. The success of this device is unlikely due to it having to duplicate the complex frequency modulated neural signals of the nerve fiber layer. Furthermore, the nerve fiber layer runs in a general radial course with many layers of overlapping fibers from different portions of the retina. Selection of appropriate nerve fibers to stimulate to produce formed vision would be extremely difficult, if not impossible. Another device involved a unit consisting of a supporting base onto which a photosensitive material such as selenium was coated. This device was designed to be inserted through an external scleral incision made at the posterior pole and would rest between the sclera and choroid, or between the choroid and retina. Light would cause a potential to develop on the photosensitive surface producing ions that would then theoretically migrate into the retina causing stimulation. However, because that device had no discrete surface structure to restrict the directional flow of charges, lateral migration and diffusion of charges would occur thereby preventing any acceptable resolution capability. Placement of that device between the sclera and choroid would also result in blockage of discrete ion migration to the photoreceptor and inner retinal layers. That was due to the presence of the choroid, choriocapillaris, Bruch's membrane and the retinal pigment epithelial layer all of which would block passage of those ions. Placement of the device between the choroid and the retina would still interpose Bruch's membrane and the retinal pigment epithelial layer in the pathway of discrete ion migration. As that device would be inserted into or through the highly vascular choroid of the posterior pole, subchoroidal, intraretinal and intraorbital hemorrhage would likely result along with disruption of blood flow to the posterior pole. One such device was reportedly constructed and implanted into a patient's eye resulting in light perception but not formed imagery. A photovoltaic device artificial retina was also disclosed in U.S. Pat. No. 5,024,223. That device was inserted into the potential space within the retina itself. That space, called the subretinal space, is located between the outer and inner layers of the retina. The device was comprised of a plurality of so-called Surface Electrode Microphotodiodes (“SEMCPs”) deposited on a single silicon crystal substrate. SEMCPs transduced light into small electric currents that stimulated overlying and surrounding inner retinal cells. Due to the solid substrate nature of the SEMCPs, blockage of nutrients from the choroid to the inner retina occurred. Even with fenestrations of various geometries, permeation of oxygen and biological substances was not optimal. Another method for a photovoltaic artificial retina device was reported in U.S. Pat. No. 5,397,350, which is incorporated herein by reference. That device was comprised of a plurality of so-called Independent Surface Electrode Microphotodiodes (ISEMCPs), disposed within a liquid vehicle, also for placement into the subretinal space of the eye. Because of the open spaces between adjacent ISEMCPs, nutrients and oxygen flowed from the outer retina into the inner retinal layers nourishing those layers. In another embodiment of that device, each ISEMCP included an electrical capacitor layer and was called an ISEMCP-C. ISEMCP-Cs produced a limited opposite direction electrical current in darkness compared to in the light, to induce visual sensations more effectively, and to prevent electrolysis damage to the retina due to prolonged monophasic electrical current stimulation. These previous devices (SEMCPs, ISEMCPs, and ISEMCP-Cs) depended upon light in the visual environment to power them. The ability of these devices to function in continuous low light environments was, therefore, limited. Alignment of ISEMCPs and ISEMCP-Cs in the subretinal space so that they would all face incident light was also difficult.”

U.S. Pat. No. 6,324,429 for a chronically implantable retinal prosthesis by Doug Shire, Joseph Rizzo, and John Wyatt, of the Massachusetts Eye and Ear Infirmary Massachusetts Institute of Technology issued Nov. 27, 2001 provides the following information, “In the human eye, the ganglion cell layer of the retina becomes a monolayer at a distance of 2.5-2.75 mm from the foveal center. Since the cells are no longer stacked in this outer region, this is the preferred location for stimulation with an epiretinal electrode array. The feasibility of a visual prosthesis operating on such a principle has been demonstrated by Humayun, et al. in an experiment in which the retinas of patients with retinitis pigmentosa, age-related macular degeneration, or similar. degenerative diseases of the eye were stimulated using bundles of insulated platinum wire. The patients were under local anesthesia, and they described seeing points of light which correctly corresponded with the region of the retina in which the stimulus was applied (Humayun, M., et al., Archiv. Ophthalmol., 114: 40-46, 1996). The form of the stimulating device was, however, not suited for chronic implantation. The threshold for perception was reported to be in the range of 0.16-70 mC/cm.sup.2. This confirmed the results of earlier experiments on animal subjects by the instant inventors and others which indicated that strong evoked cortical potentials could be observed when rabbit retinas were stimulated using passive microfabricated electrode arrays similar in some respects to the ones proposed in the current invention (Rizzo, J. F., et al., ARVO Poster Session Abstract, Investigative Ophthalmology and Visual Science, 37: S707, 1996; Walter, P., et al. Investigative Ophthalmology and Visual Science, 39: S990, 1998). The instant inventors have, with others, performed three surgical procedures using microfabricated electrode arrays and similar in technique to those described by Humayun and confirmed that a consistent response to input electrical stimuli could be noted by the patient. The task of creating a retinal implant has been addressed by Chow, in U.S. Pat. No. 5,016,633, who proposed a subretinal implant based on a microphotodiode array. The procedure involved in its implantation is so biologically intrusive, however, that successful implementation of such a device in human subjects has not been reported. Furthermore, an entirely passive array will be rather insensitive under normal lighting conditions, and an array powered from outside the body by means of a direct electrical connection will likely lead to infections and again, be so intrusive as to be objectionable. Earlier designs of the present inventors placed all components of the prosthesis on the retinal surface (U.S. patent application Ser. No. 19/074,196, filed May 7, 1998, and U.S. Pat. No. 5,800,530, both of which are incorporated herein by reference). It became quickly apparent that the delicate retina could not withstand the mechanical burden which was at least partially the result of the relatively thick profile of the microelectronic components. A later prototype included one significant change in design—the bulky microelectronic components were moved anteriorly within the eye, off of the retinal surface. In this configuration, the microelectronics are held in a custom-designed intraocular lens, and only a thin ribbon containing the microelectrodes extends rearwardly to the retinal surface.”

### SUMMARY

Features and advantages of the present invention will become apparent from the following description. Applicants are providing this description, which includes drawings and examples of specific embodiments, to give a broad representation of the invention. Various changes and modifications within the spirit and scope of the invention will become apparent to those skilled in the art from this description and by practice of the invention. The scope of the invention is not intended to be limited to the particular forms disclosed and the invention covers all modifications, equivalents, and alternatives falling within the spirit and scope of the invention as defined by the claims.

The present invention provides a flexible cable comprising a cable body of a silicone material and circuits in the flexible cable body. In one embodiment, the flexible cable body comprises a multiple number of individual layers of a silicone material with circuits in the individual layers. In another embodiment, the multiple layers are stacked vertically one on the other to form the flexible cable body. In one embodiment, the silicone material is poly(dimethylsiloxane). In one embodiment, silicone material encapsulating the flexible cable body. The flexible cable is made by providing a multiplicity of substrates of a flexible silicone material, producing circuits in the substrates, and stacking the multiplicity of substrates to produce the high density flexible cable.

The present has many uses. For example, the invention has use as interface devices for artificial stimulation such as retinal, cochlear, and cortical prosthesis; and other uses. The implantable biological interface devices for artificial stimulation are stimulation devices that substitute for malfunctioning sensory neural structures. The implantable biological interface devices are important bioengineering applications that require integrating microelectronic systems with biological systems.

The invention is susceptible to modifications and alternative forms. Specific embodiments are shown by way of example. It is to be understood that the invention is not limited to the particular forms disclosed. The invention covers all modifications, equivalents, and alternatives falling within the spirit and scope of the invention as defined by the claims.

### BRIEF DESCRIPTION OF THE DRAWINGS

The accompanying drawings, which are incorporated into and constitute a part of the specification, illustrate specific embodiments of the invention and, together with the general description of the invention given above, and the detailed description of the specific embodiments, serve to explain the principles of the invention.

FIG. 1 illustrates an embodiment of a system constructed in accordance with the present invention.

FIG. 2 illustrates an embodiment of a system for connecting the ribbon cable to various electronic units.

FIG. 3 illustrates another embodiment of a system for connecting the able to various electronic units.

FIG. 4 illustrates an embodiment of a multilevel high density flexible multi level cable.

FIG. 5 illustrates an embodiment of a system of the present invention used with a retinal prosthesis.

### DETAILED DESCRIPTION OF THE INVENTION

Referring now to the drawings, to the following detailed description, and to incorporated materials, detailed information about the invention is provided including the description of specific embodiments. The detailed description serves to explain the principles of the invention. The invention is susceptible to modifications and alternative forms. The invention is not limited to the particular forms disclosed. The invention covers all modifications, equivalents, and alternatives falling within the spirit and scope of the invention as defined by the claims.

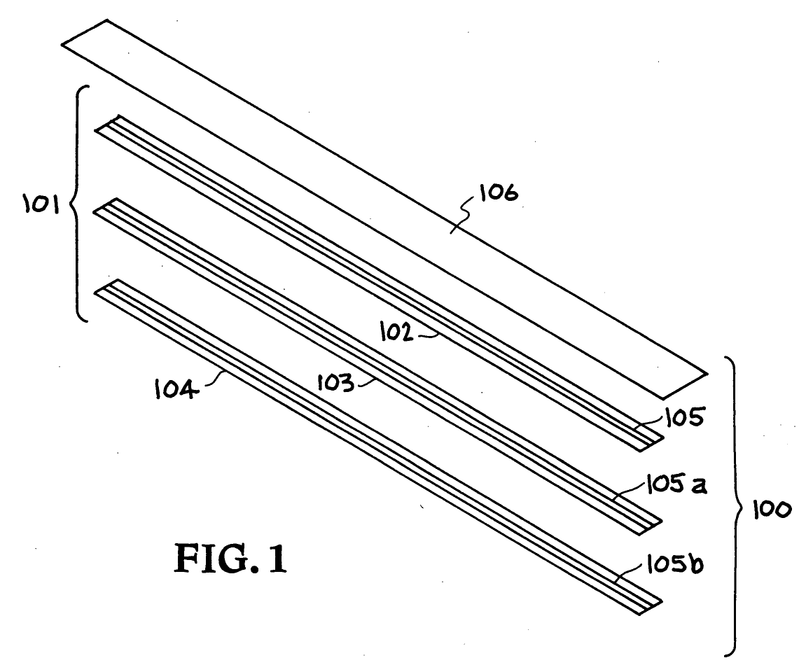

Referring now to in FIG. 1, an embodiment of a system constructed in accordance with the present invention is illustrated. The system is generally designated by the reference numeral 100. As shown in FIG. 1, the system 100 provides a multilevel high density flexible ribbon cable 101. The production of the ribbon cable 101 uses silicone based fabrication processes. The ribbon cable 101 comprises the substrate poly(dimethylsiloxane) (PDMS). A number of layers 102, 103, and 104 of PDMS are stacked to form the ribbon cable 101. Metal traces 105, 105a, 105b, etc. are patterned on each of the PDMS layers 102, 103, and 104 to form the circuit of the ribbon cable 101. The individual PDMS layers 102, 103, and 104 are bonded together to form the multilayer ribbon cable 101. The exposed ends of the metal traces 105, 105a, 105b, etc. of the ribbon cable 101 serve as the connection to a device such as an electrode, an integrated circuit, a chip, or other devices. An encapsulating layer 106 of DMS protects all components from the environment.

The system 100 has many uses. For example, the system 100 has use as smart sensors monitoring for countering terrorist threats; for sensor bugs (surveillance); for impromptu wireless networks; for implantable biological interface devices for artificial stimulation such as retinal, cochlear, and cortical prosthesis; and other uses. The implantable biological interface devices for artificial stimulation are stimulation devices that substitute for malfunctioning sensory neural structures. The implantable biological interface devices are important bioengineering applications that require integrating microelectronic systems with biological systems.

The use of electrical stimulation to recover lost bodily functions has been pursued for over a century; however, the technology necessary to create an implantable electrical stimulation system has been in existence only for a few decades. A prime example of such a system is the cardiac pacemaker. This system is comprised of a single stimulation electrode with the circuitry and power supply housed in a rigid titanium canister for protection from biodegradation. Requiring low stimulation frequency and no real-time external control unit, a rechargeable battery is sufficient to power this device. However, a great deal of complexity is added when developing a sensory implant due to the large quantity of information that must be captured, processed, and transmitted in real-time from the surrounding environment to implanted stimulating electrodes. In this case, batteries are no longer a sufficient power supply and must be replaced by a radio frequency (RF) wireless inductive link that transmits both signal and power. In addition to requiring sophisticated data acquisition and power generating components, the size and shape of sensory implants are often dictated by anatomical space constraints.

Microtechnology offers a tremendous opportunity to develop microelectronic components capable of interfacing with intricate biological systems. Since neural implantable devices are intended for long-term implants that interfaces with delicate tissue, vital biological and physical design requirements must be met. The device is required to: (1) conform to the biological tissue without inducing detrimental stress, (2) be flexible and robust to withstand handling during fabrication and implantation, (3) be biocompatible for permanent implantation, and (4) be capable of interfacing to an integrated circuit (IC) chip and supporting electronics to receive power and data wirelessly to allow for complete system integration. Foreseeing the incompatibilities of conventional microfabrication materials, such as silicon and glass, polymer-based technologies are currently being pursued. Although polymers such as polyimide have well-established microfabrication processing technology history, they lack the conformability and softness offered by various types of silicone rubbers.

The system 100 provides a polymer-based platform for producing high density ribbon cable 101. Applicants achieve the high density electrode array by applying a multi-level fabrication approach. The approach leverages advances for integrated bioMEMS and microfluidic systems. Applicants have demonstrated 2D and 3D metallization of PDMS (silicone rubber) substrates. Applicants have also demonstrated the multi-layer ribbon cable by bonding 2D and 3D PDMS films. Applicants have also worked on integrating ICs with a PDMS implantable microelectrode array. Silicon IC chips can be irreversibly bonded to PDMS simply by cleaning in alcohol, exposing to an oxygen plasma, then bringing the two surfaces into contact. At the same time as the IC is bonded, electrical connects are established. The PDMS approach is inexpensive, and the process is rapid turn-around and amenable to batch processing. PDMS has very low water permeability and protects components from environment. After curing, PDMS can be bonded to itself or other material such as glass or silicon. PDMS is flexible and will conform to curved surfaces.

In order for the PDMS ribbon cable 101 to be an ideal, low cost, integration and packaging platform, demonstration of metalization to create the circuit lines 105, 105a, and 105b is important. The metalization comprises metal deposition to create the circuit lines 105, 105a, and 105b. The PDMS ribbon cable 101 can be connected to various electronic units by the conductive lines 105, 105a, and 105b.

The drawings and written description illustrate a number of specific embodiments of the present invention. These embodiments and other embodiments give a broad illustration of the invention. Various changes and modifications within the spirit and scope of the invention will become apparent to those skilled in the art. Applicants will describe four embodiments involving creating the circuit lines 105, 105a, and 105b and connections to various electronic units.

In one embodiment, applicants produce three-dimensional microfluidic channels in the PDMS substrate 101. Applicants then fill the microfluidic networks with liquid conductive ink. Applicants then cure the ink to produce embedded conducting networks within the PDMS substrate 101. A syringe is used to inject the ink into the channels to allow for an even distribution throughout the structure. Alternatively, a vacuum can be used to draw the ink through the microfluidic network. After the ink is dispersed throughout the channels it is then cured producing conductive micron-scale wires.

In a preliminary experiment, a set of four channels with different diameters was created in a 49 mm long block of PDMS with the conductive ink (Conductive Compounds, AG-500, silver filled electrically conductive screen printable ink/coating) injected into each channel. Channel sizes ranged from 100 microns to 378 microns in diameter. After curing, all four lines were found to be electrically continuous.

The Microfluidic Networks can be produced as described in International Patent No. WO0189787 published Nov. 29, 2001 and May 30, 2002, titled “MICROFLUIDIC SYSTEMS INCLUDING THREE- DIMENSIONALLY ARRAYED CHANNEL NETWORKS,” to the President and Fellows of Harvard College invented by Anderson et al. This patent describes methods for fabricating improved microfluidic systems, which contain one or more levels of microfluidic channels. The microfluidic channels can include three-dimensionally arrayed networks of fluid flow paths therein including channels that cross over or under other channels of the network without physical intersection at the points of cross over. The microfluidic networks of the can be fabricated via replica molding processes. International Patent No. WO0189787 and the information and disclosure provided thereby is incorporated herein by reference.

In another embodiment, applicants produce three-dimensional microfluidic channels in the PDMS substrate 101 using a stamp to place the ink in a desired pattern on layers of PDMS. A description of a deformable stamp for patterning a surface is shown in U.S. patent application Ser. No. 2002/0050220 for a deformable stamp for patterning three-dimensional surfaces by Olivier Schueller, Enoch Kim, and George Whitesides published May 5, 2002. U.S. patent application Ser. No. 2002/0050220 is incorporated herein by reference.

The stamp can be placed in contact with an entire 3-dimensional object, such as a rod, in a single step. The stamp can also be used to pattern the inside of a tube or rolled over a surface to form a continuous pattern. The stamp may also be used for fluidic patterning by flowing material through channels defined by raised and recessed portions in the surface of the stamp as it contacts the substrate. The stamp may be used to deposit self-assembled monolayers, biological materials, metals, polymers, ceramics, or a variety of other materials. The patterned substrates may be used in a variety of engineering and medical applications. This approach can be used to pattern the conductive inks to produce multi level metalization as follows:
1. An etched substrate of silicon, glass, or comparable type is used to mold the PDMS to a desired pattern. Photoresist or other material can also be patterned onto the silicon or glass substrate to create the mold.
2. The PDMS is applied on the mold, allowed to cure and then peeled away from the substrate forming a stamp.
3. The conductive ink is then spin coated onto a second application wafer to achieve a thin coating.
4. The PDMS stamp is then applied to this wafer allowing for the ink to transfer from the application wafer to the stamp.
5. The PDMS stamp with the ink applied to it is aligned with the PDMS-coated substrate wafer and placed in contact, then removed, transferring the ink.
6. The ink is then allowed to cure at the appropriate temperature for proper adhesion.
7. Once the ink is cured a layer of photoresist is applied and patterned to produce posts that will form the interconnects between metal layers. This is done using photolithography techniques.
8. A second layer of PDMS is applied to the substrate wafer to passivate the first layer of metal without exceeding the height of the photoresist posts.
9. After curing the PDMS, the photoresist posts are removed in acetone, leaving vias down to the underlying metal layer.
10. The holes are filled either by filling with conductive ink or by electroplating.
11. For multi-layer metalization steps 3-11 are repeated until the desired number of levels are achieved.

Another embodiment of a system for creating the circuit lines 105, 105a, and 105b is photolithography. Photoresist is spun onto the substrate wafer and patterned, exposing the underlying PDMS layer in regions where the conductive ink is to be applied. The conductive ink is then spread onto the substrate, either by spin-coating or spraying. After curing, the photoresist is removed in acetone, lifting off the undesired conductive ink. This process can be replicated until the desired levels are completed.

Another embodiment of a system for creating the circuit lines 105, 105a, and 105b is screen printing. To avoid the use of photoresist and the possibility of losing excessive amounts of ink in the photolithography process, the ink can simply be screen printed on using traditional techniques. A permeable screen mesh of either monofilament polyester or stainless steel is stretched across a frame. The frame with a stencil with the desired pattern is placed on top of the wafer with cured PDMS. Using a squeegee the conductive ink is pushed through the stencil and onto the substrate wafer. Another screen mesh with stencil is used to apply the appropriate interconnections for each layer of metalization. After which a second layer of PDMS is applied to the substrate wafer to passivate the first layer of metal without exceeding the height of the metal interconnections. This process is repeated until the desired number of levels is achieved.

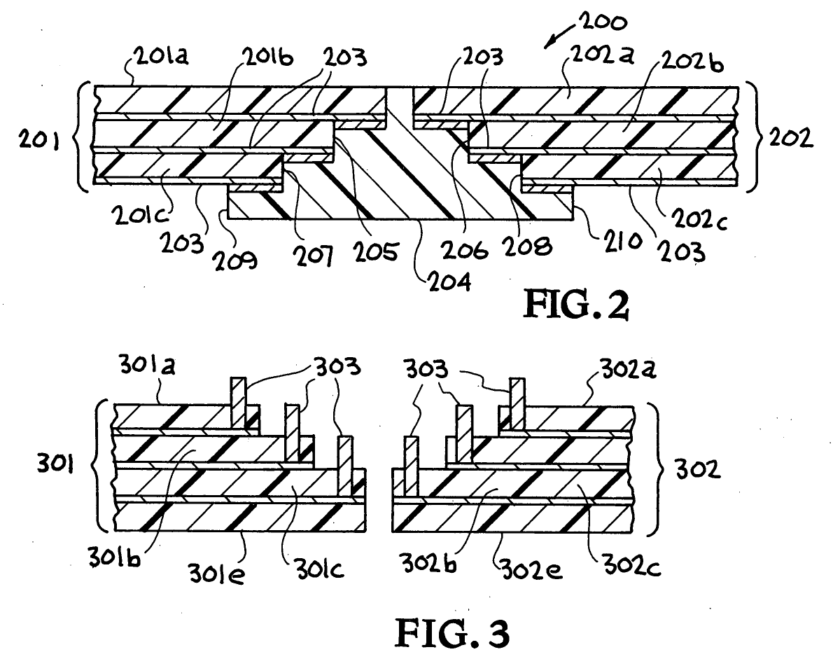

The PDMS ribbon cable can be connected to various electronic units by the ribbon cable's conductive lines. Referring now to FIG. 2, an embodiment of a system for connecting the PDMS ribbon cable to various electronic units is illustrated. The system is designated generally by the reference numeral 200. As shown in FIG. 2, a pair of ribbon cables 201 and 202 comprise a number of layers of poly(dimethylsiloxane) (PDMS), each with metal traces.

The ribbon cable 201 comprises a number of layers 201a, 201b, and 201c. The layers 201a, 201b, and 201c are comprised of PDMS. The layers 201a, 201b, and 201c are stacked to form the ribbon cable 201. Metal traces 203 are patterned on each of the PDMS layers 201a, 201b, and 201c to form the circuits of the ribbon cable 201. The individual PDMS layers 201a, 201b, and 201c are bonded together to form the multilayer ribbon cable 201. The exposed ends of the metal traces 203 of the various layers 201a, 201b, and 201c of the ribbon cable 201 serve as the connection to an electrode array 204. An encapsulating layer 201E of PDMS protects all components of the ribbon cable 201 from the environment. The PDMS ribbon cable 201 is connected to the electrode 204 by the conductive lines 201a, 201b, and 201c. As shown in FIG. 2, the ends of the conductive lines 203 are exposed for connection to the electrode array 204.

The ribbon cable 202 comprises a number of layers 202a, 202b, and 202c. The layers 202a, 202b, and 202c are comprised of PDMS. The layers 202a, 202b, and 202c are stacked to form the ribbon cable 202. Metal traces 203 are patterned on each of the PDMS layers 202a, 202b, and 202c to form the circuits of the ribbon cable 202. The individual PDMS layers 202a, 202b, and 202c are bonded together to form the multilayer ribbon cable 202. The exposed ends of the metal traces 203 of the various layers 202a, 202b, and 202c of the ribbon cable 202 serve as the connection to an electrode 204. An encapsulating layer 202E of PDMS protects all components of the ribbon cable 202 from the environment. The PDMS ribbon cable 202 is connected to the electrode 204 by the conductive lines 202a, 202b, and 202c. As shown in FIG. 2, the ends of the conductive lines 203 are exposed for connection to the electrode array 204.

The electrode array 204 includes shoulders 205, 206, 207, 208, 209, and 210. When the ribbon cables 201 and 202 are positioned on the electrode 204 the shoulders 205, 206, 207, 208, 209, and 210 contact the ends of the conductive lines 203. The ends of the conductive lines 203 of ribbon cable layers 201a and 202a contact the shoulders 205 and 206 respectively. The ends of the conductive lines 203 of ribbon cable layers 201b and 202b contact the shoulders 207 and 208 respectively. The ends of the conductive lines 203 of ribbon cable layers 201c and 202c contact the shoulders 209 and 210 respectively.

Referring now to FIG. 3, another embodiment of a system for connecting the PDMS ribbon cable to various electronic units is illustrated. The system is designated generally by the reference numeral 300. As shown in FIG. 3, a pair of ribbon cables 301 and 302 comprise a number of layers of poly(dimethylsiloxane) (PDMS), each with metal traces.

The ribbon cable 301 comprises a number of layers 301a, 301b, and 301c. The layers 301a, 301b, and 301c are comprised of PDMS. The layers 301a, 301b, and 301c are stacked to form the ribbon cable 301. Metal traces are patterned on each of the PDMS layers 301a, 301b, and 301c to form the circuits of the ribbon cable 301 as previously described. The individual PDMS layers 301a, 301b, and 301c are bonded together to form the multilayer ribbon cable 301. An encapsulating layer 301E of PDMS protects all components of the ribbon cable 301 from the environment. The PDMS ribbon cable 301 is connected to electrodes 303. The electrodes 303 contact the metal traces in the individual PDMS layers 301a, 301b, and 301c.

The ribbon cable 302 comprises a number of layers 302a, 302b, and 302c. The layers 302a, 302b, and 302c are comprised of PDMS. The layers 302a, 302b, and 302c are stacked to form the ribbon cable 302. Metal traces are patterned on each of the PDMS layers 302a, 302b, and 302c to form the circuits of the ribbon cable 302 as previously described. The individual PDMS layers 302a, 302b, and 302c are bonded together to form the multilayer ribbon cable 302. An encapsulating layer 302E of PDMS protects all components of the ribbon cable 302 from the environment. The PDMS ribbon cable 302 is connected to electrodes 303. The electrodes 303 contact the metal traces in the individual PDMS layers 302a, 302b, and 302c.

The electrodes 303 are produced by forming holes in the individual PDMS layers 301a, 301b, 301c, 302a, 302b, and 302c. The holes are filled with metal to form the electrodes 303. A description of a system for forming holes and filling the holes is shown in U.S. patent application Ser. No. 2003/0097166 published May 22, 2003 for a flexible electrode array for artificial vision by Peter Krulevitch, Dennis Polla, Mariam Maghribi, and Julie Hamilton. U.S. patent application Ser. No. 2003/0097166 is incorporated herein by reference.

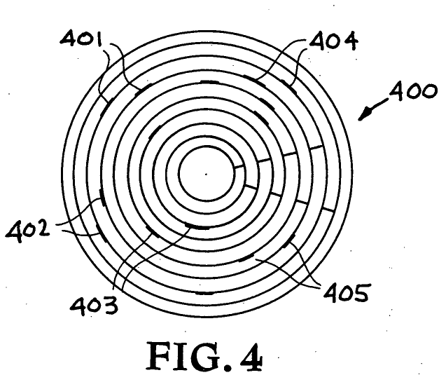

Referring now to in FIG. 4, an embodiment of a system constructed in accordance with the present invention is illustrated. The system is generally designated by the reference numeral 400. As shown in FIG. 4, the system 400 provides a multilevel high density flexible multi level cable 401. The production of the multi-level cable 401 uses silicone based fabrication processes. The multi-level cable 401 comprises the substrate poly(dimethylsiloxane) (PDMS). A number of circumfrential layers of PDMS are combined to form the multi-level cable 401. Metal traces 403, 404, and 405 are patterned in each of the PDMS layers to form the circuit of the multi-level cable 401. The individual PDMS layers are bonded together to form the multilayer multi-level cable 401. The metal traces 403, 404, 405 of the multi-level cable 401 serve as the connection to a device such as an electrode, an integrated circuit, a chip, or other devices. An encapsulating layer of PDMS protects all components from the environment.

The system 400 provides a polymer-based platform for producing high density multi-level cable 401. Applicants achieve the high density electrode array by applying a multi-level fabrication approach. The approach leverages advances for integrated bioMEMS and microfluidic systems. Applicants have demonstrated 2D and 3D metallization of PDMS (silicone rubber) substrates. Applicants have also demonstrated the multi-layer multi-level cable by bonding 2D and 3D PDMS films. Applicants have also worked on integrating ICs with a PDMS implantable microelectrode array. Silicon IC chips can be irreversibly bonded to PDMS simply by cleaning in alcohol, exposing to an oxygen plasma, then bringing the two surfaces into contact. At the same time as the IC is bonded, electrical connects are established. The PDMS approach is inexpensive, and the process is rapid turn-around and amenable to batch processing. PDMS has very low water permeability and protects components from environment. After curing, PDMS can be bonded to itself or other material such as glass or silicon.

PDMS is flexible and will conform to curved surfaces.

In order for the PDMS multi-level cable 401 to be an ideal, low cost, integration and packaging platform, demonstration of metalization to create the circuit lines 403, 404, and 405 is important. The metalization comprises metal deposition to create the circuit lines 403, 404, and 405. The PDMS multi-level cable 401 can be connected to various electronic units by the conductive lines 403, 404, and 405.

The drawings and written description illustrate a number of specific embodiments of the present invention. These embodiments and other embodiments give a broad illustration of the invention. Various changes and modifications within the spirit and scope of the invention will become apparent to those skilled in the art. Applicants will describe four embodiments involving creating the circuit lines 405, 405a, and 405b and connections to various electronic units.

In one embodiment, applicants produce three-dimensional microfluidic channels in the PDMS substrate 401. Applicants then fill the microfluidic networks with liquid conductive ink. Applicants then cure the ink to produce embedded conducting networks within the PDMS substrate 401. A syringe is used to inject the ink into the channels to allow for an even distribution throughout the structure. Alternatively, a vacuum can be used to draw the ink through the microfluidic network. After the ink is dispersed throughout the channels it is then cured producing conductive micron-scale wires.

In a preliminary experiment, a set of four channels with different diameters was created in a 49 mm long block of PDMS with the conductive ink (Conductive Compounds, AG-500, silver filled electrically conductive screen printable ink/coating) injected into each channel. Channel sizes ranged from 400 microns to 378 microns in diameter. After curing, all four lines were found to be electrically continuous.

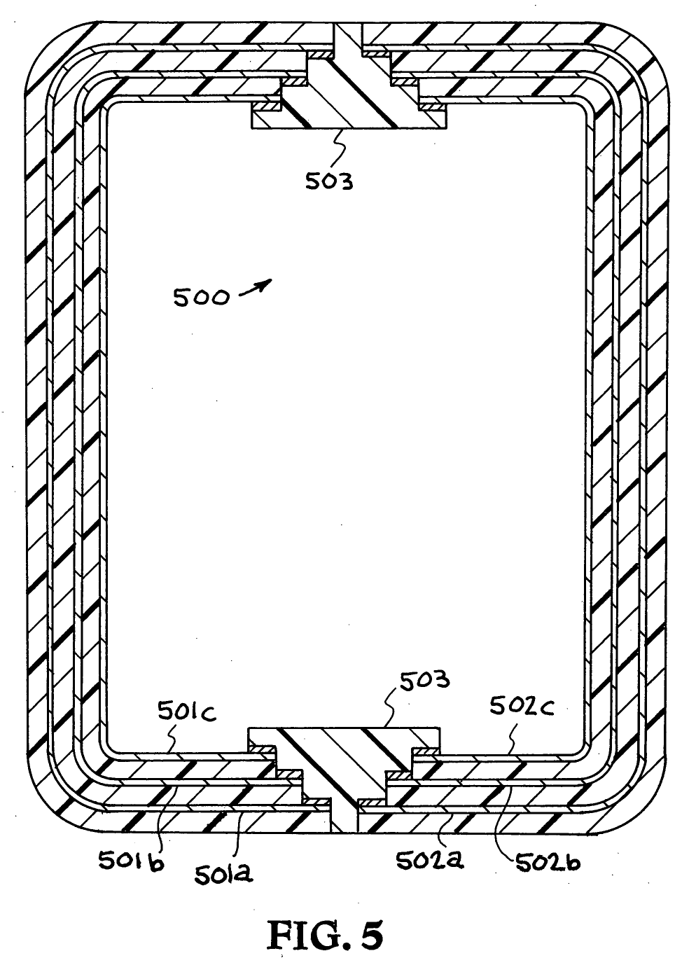

Referring now to FIG. 5, an embodiment of a system of the present invention used with a retinal prosthesis is illustrated. This embodiment of the present invention provides a system that restores vision to people with certain types of eye disorders. This type of system is described in U.S. patent application Ser. No. 2003/0097165 published May 22, 2003 by Peter Krulevitch, Dennis L. Polla, Mariam Maghribi, Julie Hamilton, and Mark S. Humayun for a Flexible Electrode Array for Artificial Vision. U.S. patent application Ser. No. 2003/0097165 published May 22, 2003 is incorporated herein by this reference.

The Flexible Electrode Array for Artificial Vision system uses a video camera that captures an image. The image is sent to a patient's eye. An electronics package within the eye receives the image signal and sends it to an electrode array by a cable system. The electrode array is made of a compliant material with electrodes and conductive leads embedded in it. The electrodes contact tissue of the retina within the eye. The electrode array stimulates retinal neurons. The retinal neurons transmit the signal to be decoded in the brain.

The cable system transmits the signal to the electrode array is illustrated in FIG. 5. The cable system is generally designated by the reference numeral 500. The system 500 provides a multilevel high density flexible multi- level cable made up of the layers 501a, 501b, 501c, 502a, 502b, and 502c. The layers of PDMS are combined to form the multi-level cable 501. Metal traces are patterned in each of the PDMS layers to form the circuit of the multi-level cable 501.

The system 500 provides a polymer-based platform for producing high density multi-level cable 501. Applicants achieve the high density electrode array by applying a multi-level fabrication approach. The approach leverages advances for integrated bioMEMS and microfluidic systems. Applicants have demonstrated 2D and 3D metallization of PDMS (silicone rubber) substrates. Applicants have also demonstrated the multi-layer multi-level cable by bonding 2D and 3D PDMS films. Applicants have also worked on integrating ICs with a PDMS implantable microelectrode array. Silicon IC chips can be irreversibly bonded to PDMS simply by cleaning in alcohol, exposing to an oxygen plasma, then bringing the two surfaces into contact. At the same time as the IC is bonded, electrical connects are established. The PDMS approach is inexpensive, and the process is rapid turn-around and amenable to batch processing. PDMS has very low water permeability and protects components from environment. After curing, PIDIVIS can be bonded to itself or other material such as glass or silicon. PDMS is flexible and will conform to curved surfaces.

The electronics package is connected to the cable system 500 by the connection 503. The electrode 502 stimulates the retina with a pattern of electrical pulses based on the sensed image signal. The system 500 receives the transmitted signal, derives power from the transmitted signal, decodes image data, and produces an electrical stimulus pattern at the retina based on the image data.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents, and alternatives falling within the spirit and scope of the invention as defined by the following appended claims.

The invention claimed is:

1. A flexible cable apparatus, comprising:
a cable body of a silicone material, and
circuits in said flexible cable body of a silicone material.

2. The flexible cable apparatus of claim 1 wherein said flexible cable body of a silicone material comprises a multiple number of individual layers of a silicone material with circuits in said multiple number of individual layers of a silicone material.

3. The flexible cable apparatus of claim 1 wherein said flexible cable body of a silicone material comprises a multiple number of individual layers of a silicone material with circuits in said multiple number of individual layers of a silicone material, said multiple layer stacked one on the other to form said flexible cable body.

4. The flexible cable apparatus of claim 1 wherein said flexible cable body of a silicone material comprises a multiple number of individual layers of a silicone material with circuits in said multiple number of individual layers of a silicone material, said multiple layer stacked vertically one on the other to form said flexible cable body.

5. The flexible cable apparatus of claim 1 wherein said flexible cable body of a silicone material comprises a multiple number of individual layers of a silicone material with circuits in said multiple number of individual layers of a silicone material, said multiple layer stacked in a radial arrangement one on the other to form said flexible cable body.

6. The flexible cable apparatus of claim 1 wherein said silicone material is poly(dimethylsiloxane).

7. The flexible cable apparatus of claim 1 wherein said silicone material contains a multiplicity of separate metal traces in said silicone material to form said circuits.

8. The flexible cable apparatus of claim 1 wherein said silicone material contains a multiplicity of separate fluidic circuits in said silicone material to form said circuits.

9. The flexible cable apparatus of claim 1 wherein said cable body comprises a stratum of individual sections of silicone material with metal circuits in each of said sections of said silicone material.

10. The flexible cable apparatus of claim 1 wherein said cable body comprises a stratum of individual flat layers of silicone material with metal circuits in each of said flat layers of said silicone material.

11. The flexible cable apparatus of claim 1 wherein said cable body comprises a stratum of circular layers of silicone material with metal circuits in each of said circular layers of said silicone material.

12. The flexible cable apparatus of claim 1 wherein said cable body comprises a stratum of individual sections of silicone material with metal circuits in each of said sections of said silicone material and silicone material encapsulating said stratum of individual sections of silicone material with metal circuits.

13. The flexible cable apparatus of claim 1 wherein said flexible cable body of a silicone material comprises a multiplicity of flat layers of poly(dimethylsiloxane).

14. A high density flexible cable apparatus, comprising:
cable body means for providing a high density flexible silicone material cable body, and
circuit means in said cable body means for providing a circuit in said cable body.

15. The high density flexible cable apparatus of claim 14 wherein said cable body means comprises poly(dimethylsiloxane).

16. The high density flexible cable apparatus of claim 14 wherein said circuit mean comprises a multiplicity of separate metal traces in said cable body that form said circuits.

17. The high density flexible cable apparatus of claim 14 wherein said circuit mean comprises fluidic circuits in said cable body that form said circuits.

18. The high density flexible cable apparatus of claim 14 wherein said cable body means comprises a stratum of individual sections of silicone material with metal circuits in each of said sections of said silicone material.

19. The high density flexible cable apparatus of claim 14 wherein said cable body means comprises a stratum of individual flat layers of silicone material with metal circuits in each of said flat layers of said silicone material.

20. The high density flexible cable apparatus of claim 14 wherein said cable body means comprises a stratum of circular layers of silicone material with metal circuits in each of said circular layers of said silicone material.

21. The high density flexible cable apparatus of claim 14 wherein said cable body means comprises a stratum of individual sections of silicone material with metal circuits in each of said sections of said silicone material and silicone material encapsulating said stratum of individual sections of silicone material with metal circuits.

22. The high density flexible cable apparatus of claim 14 wherein said cable body means comprises a multiplicity of flat layers of poly(dimethylsiloxane).

23. A method of making a high density flexible cable, comprising the steps of:
providing a multiplicity of substrates of a flexible silicone material,
producing circuits in said substrates, and
stacking said multiplicity of substrates to produce the high density flexible cable.

24. The method of making a high density flexible cable of claim 23, including the step of encapsulating said multiplicity of substrates and said circuits with a flexible silicone material.

25. The method of making a high density flexible cable of claim 23, wherein said step of providing a multiplicity of substrates of a flexible silicone material comprises providing a multiplicity of substrates of poly(dimethylsiloxane).

26. The method of making a high density flexible cable of claim 23, wherein said step of producing circuits in said substrates comprises producing electronic circuits in said substrates.

27. The method of making a high density flexible cable of claim 23, wherein said step of producing circuits in said substrates comprises producing fluidic circuits in said substrates.

28. The method of making a high density flexible cable of claim 23, wherein said step of providing a multiplicity of substrates of a flexible silicone material comprises providing a multiplicity of flat substrates and said step of stacking said multiplicity of substrates to produce the high density flexible cable comprises stacking said multiplicity of substrates on top of each other to produce the high density flexible cable.

29. The method of making a high density flexible cable of claim 23, wherein said step of providing a multiplicity of substrates of a flexible silicone material comprises providing a multiplicity of flat substrates and said step of stacking said multiplicity of substrates to produce the high density flexible cable comprises stacking said multiplicity of substrates radially to produce the high density flexible cable.
